(19) United States
(12) Patent Application Publication
(10) Pub. No.: US 2022/0310518 A1
(43) Pub. Date: Sep. 29, 2022

(54) EMBEDDED BRIDGE ARCHITECTURE WITH THINNED SURFACE

(71) Applicant: Intel Corporation, Santa Clara, CA (US)

(72) Inventors: Haobo CHEN, Gilbert, AZ (US); Xiaoying GUO, Chandler, AZ (US); Hongxia FENG, Chandler, AZ (US); Kristof DARMAWIKARTA, Chandler, AZ (US); Bai NIE, Chandler, AZ (US); Tarek A. IBRAHIM, Mesa, AZ (US); Gang DUAN, Chandler, AZ (US); Jeremy D. ECTON, Gilbert, AZ (US); Sheng C. LI, Gilbert, AZ (US); Leonel ARANA, Phoenix, AZ (US)

(21) Appl. No.: 17/213,147

(22) Filed: Mar. 25, 2021

(51) Int. Cl. H01L 23/538; H01L 23/498; H01L 23/00; H01L 21/48

(52) U.S. Cl. CPC H01L 23/5383; H01L 23/49816; H01L 24/16; H01L 21/4857; H01L 24/11; H01L 2224/16227; H01L 2224/111; H01L 2924/1511; H01L 2924/15331

(57) ABSTRACT

Embodiments disclosed herein include a multi-die packages with an embedded bridge and a thinned surface. In an example, a multi-die interconnect structure includes a package substrate having a cavity. A bridge die is in the cavity of the package substrate, the bridge die including silicon. A dielectric material is over the package substrate, over the bridge die, and in the cavity. A plurality of conductive bond pads is on the dielectric material. The multi-die interconnect structure further includes a plurality of conductive pillars, individual ones of the plurality of conductive pillars on a corresponding one of the plurality of conductive bond pads. A solder resist material is on the dielectric material, on exposed portions of the plurality of conductive bond pads, and laterally surrounding the plurality of conductive pillars. The plurality of conductive pillars has a top surface above a top surface of the solder resist material.

### TECHNICAL FIELD

Embodiments of the present disclosure relate to semiconductor devices, and more particularly to a multi-die package with an embedded bridge and a thinned surface.

### BACKGROUND

The demand for miniaturization of form factor and increased levels of integration for high performance are driving sophisticated packaging approaches in the semiconductor industry. One such approach is to use die partitioning to enable miniaturization of small form factor and high performance. Such architectures depend on fine die-to-die interconnects to couple the partitioned dies together. Embedded multi-die interconnect bridges (EMIBs) have been used to provide the fine die-to-die interconnects. However, EMIBs also have their own integration challenges.

One challenge is that EMIBs suffer from a high cumulative bump thickness variation (BTV). BTV is becoming an even greater engineering hurdle as more EMIBs are included in a package and as the sizes of the EMIBs increase. Placing the EMIBs onto a glass patch has been proposed to reduce the BTV and improve warpage. However, the glass patch is a thick substrate that has low thermal conductivity. Accordingly, thermocompression bonding (TCB) may not be suitable for the mid-level interconnects (MLIs). Accordingly, the pitch of the MLIs needs to be increased in order to accommodate alternative bonding techniques, such as traditional chip attach module (mass reflow) process. Increasing the pitch of the MLIs may require the use of one or more redistribution layers disposed over the glass patch. The redistribution layers negate the BTV benefits provided by the glass, and may not be a desirable solution.

### BRIEF DESCRIPTION OF THE DRAWINGS

FIGS. 1-6, 7A, 8 and 9 illustrate cross-sectional views representing various operations in the fabrication of a multi-die package with an embedded bridge and a thinned surface, in accordance with an embodiment of the present disclosure.

FIG. 7B is a plan view representing an exemplary layout for the structure represented in FIG. 7A, in accordance with an embodiment of the present disclosure.

FIGS. 10A-10D are plan view illustrations of various electronic packages with an embedded bridge, in accordance with another embodiment of the present disclosure.

FIG. 11 is a schematic of a computing device built in accordance with an embodiment of the present disclosure.

### EMBODIMENTS OF THE PRESENT DISCLOSURE

Described herein are multi-die packages with embedded bridges and thinned surfaces, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As noted above, partitioned die architectures are limited, at least in part, by the interconnect architectures used to couple the partitioned dies together. For example, the use of embedded Multi-die Interconnect Bridge (EMIB) architectures can be limited by bump thickness variation (BTV) considerations. Attempts to improve BTV in EMIB architectures by using a glass patch have been unsuccessful to date. Particularly, the glass patch requires the use of mass reflow techniques for mid-level interconnects (MLIs). Since mass reflow requires larger bump pitches, a redistribution layer (RDL) must be added to the glass patch to accommodate the pitch translation. The RDL negatively impacts thickness uniformity, negating the benefits of using a glass patch.

Accordingly, embodiments disclosed herein include an electronic package that includes an embedded bridge and has a thinned surface. Embodiments may be implemented to enable surface thinning for architecture scaling of an EMIB.

To provide context, embedded Multi-die Interconnect Bridge (EMIB) is a modern and cost-effective approach to manufacture in-package high density interconnect in heterogeneous chips. There can be many embedded bridges in a single substrate, enabling high I/O density as well as tunable control of electrical interconnect paths between multiple die. In order to reduce the cost due to size shrinkage and improve package performance, reduced pitch of the first level interconnect (FLI) of die to substrate is highly sought after in the development of the next generation of EMIB products. However, current EMIB package may not be extendable to below 45 micron pitch with cost-efficient processes as there can be a limit to the minimum dimension that can be lithographically defined and may be a concern over the mechanical reliability of small vias with laser-induced via tapering.

Additionally, a high-resolution solder resist with advanced litho-patterning capability may not be readily accessible. In accordance with an embodiment of the present disclosure, an EMIB is fabricated using a litho-via-based process flow to provide an improved alignment between a FLI via to a surface copper (Cu) pad. Additionally, improved FLI scaling can be achieved without using a laser-based process.

A traditional EMIB build process can include laser drilling of a solder resist opening over an interconnect bridge and can be difficult to scale. Laser-defined via taper may induce via reliability issues since the taper can lead to smaller via diameter at the bottom. It is to be appreciated that if an SRO bottom diameter is reduced below around 16 microns, then there can be an increased chance to have bump separation or delamination. A lithographically-defined via process can be applied to build-up dielectrics, but build-up dielectrics may not have optimized material properties/chemical resistance like a solder resist to pass all substrate backend and assembly reliability processes without any issues. Also, solder resist material can also be difficult to planarize to achieve low surface roughness (Ra) for subsequent downstream backend processes and assembly. Planarization on build-up dielectrics can also be extremely costly and difficult to achieve good within panel uniformity for substrate build up with high yield.

In accordance with one or more embodiments of the present disclosure, a litho-based via process is implemented to provide an improved alignment between a FLI via to a surface conductive pad since with litho to litho alignment. Instead of planarizing build-up dielectrics with poor chemical resistance, in one embodiment, solder resist materials are used that enable solder resist thinning for via reveal. In one embodiment, a solder resist thinning process is used to control solder resist thickness of a surface insulator. As a result, in one embodiment, a very flat/uniform thickness can be achieved for the “thinner” process.

Advantages of implementing embodiments of the present disclosure can include: (1) bump pitch scaling using lithographically defined via processing; (2) since the via is litho-defined, the process can enable a straight taper that can improve via integrity; (3) a highly filled solder resist material can provide chemical resistance and enhanced crack resistance performance; (4) solder resist thinning is a relative high throughput wet process that enables precise control of the development depth, (5) a domed Ni/Sn interface can aid with solder wicking during reflow for pitch scaling; and/or (6) non-planarization of copper, whereas planarization can otherwise damage a Cu pillar top and embed residues that are difficult to remove and can result in reliability issues if not removed.

In accordance with embodiments described herein, described architectures can be detected by x-SEM imaging. Litho-defined vias (e.g., pillars) have minimal taper compared to laser drilled vias. There can also be clearly defined boundary between the pillar surface and the bump due to a separate plating operation. Copper pillars can be slightly protruded after thinning. As such, a FLI bump (e.g., Cu/Ni) may be domed and not flat or recessed as would otherwise be seen in traditional processing. Additionally, solder resist thinning can provide a relatively smooth surface Ra (e.g., less than about 120nm) and the solder resist composition detectable by EDX may be different in comparison to build-up dielectrics. Finally, since the solder resist is also litho-definable, solder resist thinning can provide flexibility to allow the development of an epoxy trench which will be unique in comparison to a state-of-the-art process flow with build-up dielectrics and planarization for via reveal.

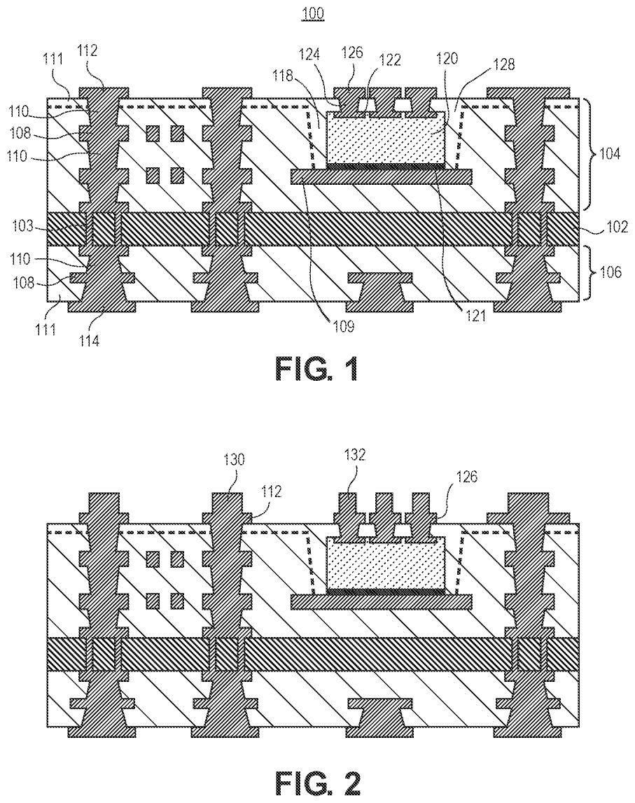

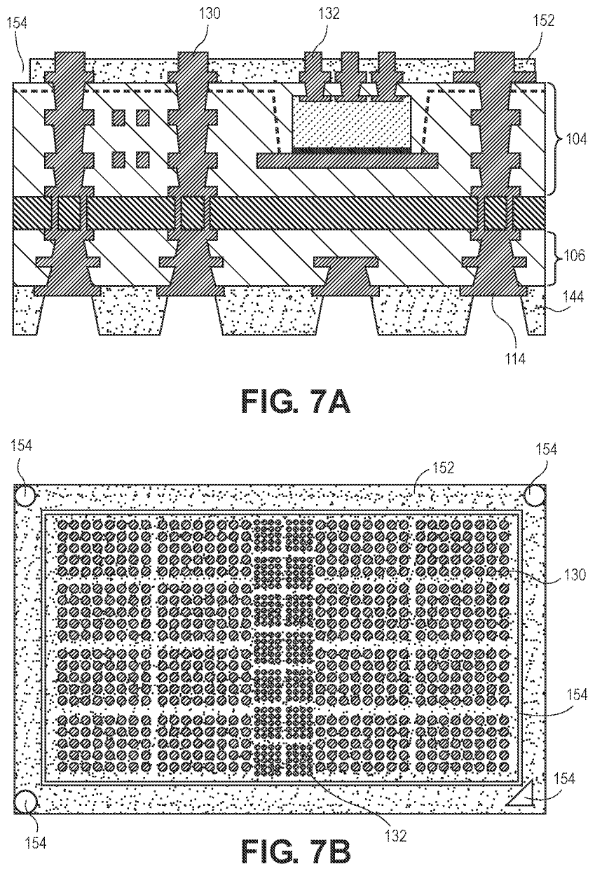

As an exemplary process flow and resulting structure, FIGS. 1-6, 7A, 8 and 9 illustrate cross-sectional views representing various operations in the fabrication of a multi-die package with an embedded bridge and a thinned surface, in accordance with an embodiment of the present disclosure. FIG. 7B is a plan view representing an exemplary layout for the structure represented in FIG. 7A, in accordance with an embodiment of the present disclosure.

Referring to FIG. 1, fabrication of a multi-die interconnect structure is based on a starting structure 100 fabricated using a bridge die embedding process. Starting structure 100 includes a package substrate 102/104/106 having a cavity 118 therein. A bridge die 120, such as a silicon bridge die is placed in the cavity 118. In one embodiment, the bridge die 120 is attached to a conductive line 109 exposed at the bottom of cavity 118 using an adhesive 121, such as a die attach film.

In a particular embodiment, package substrate 102/104/106 includes a core 102, an upper substrate portion 104, and a lower substrate portion 106, as is depicted. The upper substrate portion 104 and the lower substrate portion 106 include layers of conductive lines 108 and conductive vias 110 in a dielectric material 111, which may be composed of multiple build-up dielectric layers. Conductive lines 108 and conductive vias 110 in the upper substrate portion 104 can be coupled to conductive lines 108 and conductive vias 110 in the lower substrate portion 106 by via bars 102 extending through the substrate core 102. It is to be appreciated that reference to a package substrate in embodiments herein may include other package substrate architectures. For example, in one embodiment, only upper substrate portion 104 is used as a package substrate which excludes core 102 and lower substrate portion 106. Nonetheless, for the exemplary process flow illustrated, a package substrate based on portions 102/104/106 is used.

With reference again to FIG. 1, a dielectric material 128 is over the upper substrate portion 104, over the bridge die 120, and in the cavity 118. Conductive bond pads 112 are on the dielectric material 128 on the upper substrate portion 104. The conductive bond pads 112 are coupled to conductive vias 110 in the upper substrate portion 104. Conductive bond pads 126 are also on the dielectric material 128 on the upper substrate portion 104. The conductive bond pads 126 are coupled to conductive vias 124 in the dielectric material 128. The conductive vias 124 are coupled to the bridge die 120, e.g., by bridge die bond pads 122 of the bridge die 120. In the case that the package substrate includes a lower substrate portion, in one embodiment, conductive bond pads 114 are on the lower substrate portion 106. The conductive bond pads 114 are coupled to conductive vias 110 in the lower substrate portion 106.

In an embodiment, adjacent pads of the conductive bond pads 126 have a first pitch, and adjacent pads of the conductive bond pads 112 have a second pitch greater than the first pitch. In one such embodiment, the first pitch is less than approximately 100 μm and the second pitch is greater than approximately 100 μm.

Referring to FIG. 2, conductive pillars 130 are formed one the conductive bond pads 112. Conductive pillars 132 are formed on the conductive bond pads 126. In one embodiment, the conductive pillars 130 and 132 are fabricated using a laminated dry film resist which is lithographically exposed and then patterned to form openings over the conductive bond pads 112 and 126. A plating process, such as a copper plating process, is then used to form the conductive pillars 130 and 132, and the dry film resist is then removed.

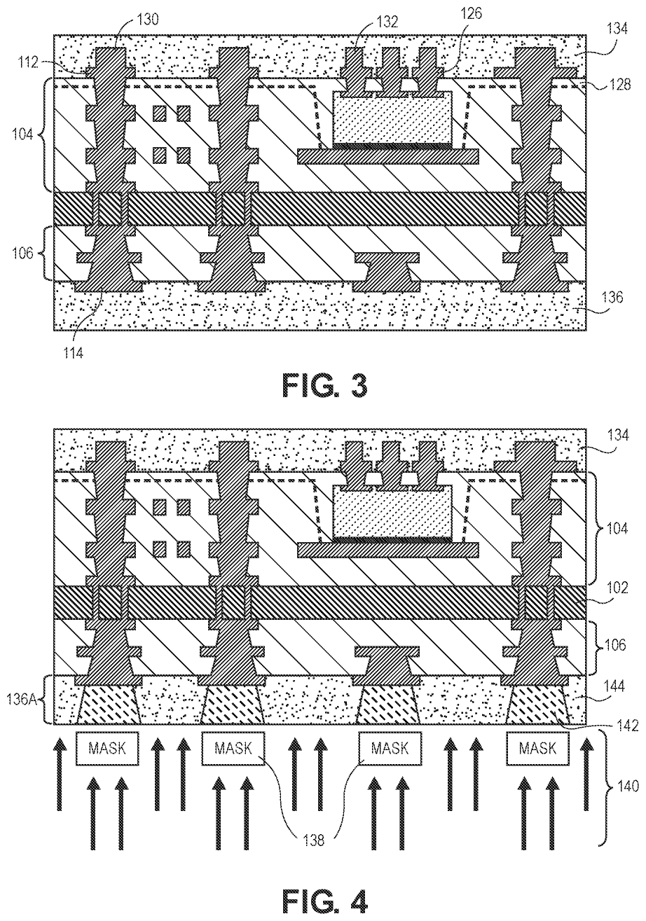

Referring to FIG. 3, a solder resist 134 is formed over the surface of the structure of FIG. 2 on the side of the upper substrate portion 104. In the case that the package substrate includes a lower substrate portion, in one embodiment, a solder resist 136 is formed over the surface of the structure of FIG. 2 on the side of the lower substrate portion 106.

Referring to FIG. 4, in the case that the package substrate includes a lower substrate portion, in one embodiment, the solder resist 136 is exposed to a lithographic process 140 using a mask 138. The lithographic process 140 forms an exposed solder mask 136A including non-exposed portions 142 and exposed portions 144. The solder resist 134 on the side of the upper substrate portion 104 is not exposed during the lithographic process 140.

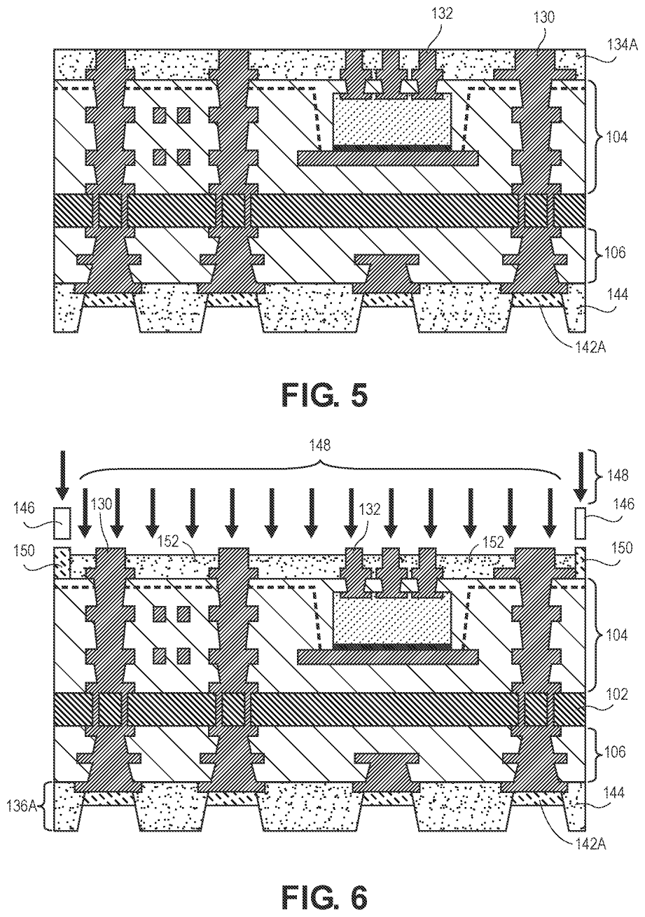

Referring to FIG. 5, the solder resist 134 on the side of the upper substrate portion 104 is thinned to form thinned solder resist 134A. In one embodiment, thinned solder resist 134A exposes a top surface of the conductive pillars 130 and 132. In a particular embodiment, thinned solder resist 134A is co-planar with a top surface of the conductive pillars 130 and 132, as is depicted. In the case that the package substrate includes a lower substrate portion, in one embodiment, the non-exposed portions 142 of the exposed solder mask 136A are also thinned to form thinned non-exposed portions 142A. The bask side and front side thinning may be performed in a same or in different process operations.

Referring to FIG. 6, the thinned solder resist 134A is exposed to a lithographic process 148 using a mask 146. The lithographic process 148 forms an exposed solder mask portion 152 and non-exposed portions 150. In one embodiment, exposure to the lithographic process 148 further thins thinned solder resist 134A, e.g., by densification during cross-linking, to provide exposed solder mask portion 152 having a top surface below a top surface of the conductive pillars 130 and 132, as is depicted. In a particular embodiment, exposed solder mask portion 152 has a top surface about 1-10 μm below the top surface of the conductive pillars 130 and 132.

Referring to FIG. 7A, the non-exposed portions 150 of the thinned solder resist 134A are removed. In the case that the package substrate includes a lower substrate portion, in one embodiment, the thinned non-exposed portions 142A of the exposed solder mask 136A are removed to expose the conductive bond pads 114.

Referring to FIG. 7B, removal of the non-exposed portions 150 of the thinned solder resist 134A provides trenches 154, which may be of varying size and/or shape. Trenches 154 may be used to facilitate downstream handling of a multi-die interconnect structure. It is to be appreciated that the layout in FIG. 7B is merely one possible exemplary layout showing a location of the conductive pillars 130 and 132 exposed through the exposed solder mask portion 152 on the side of the top substrate portion 104.

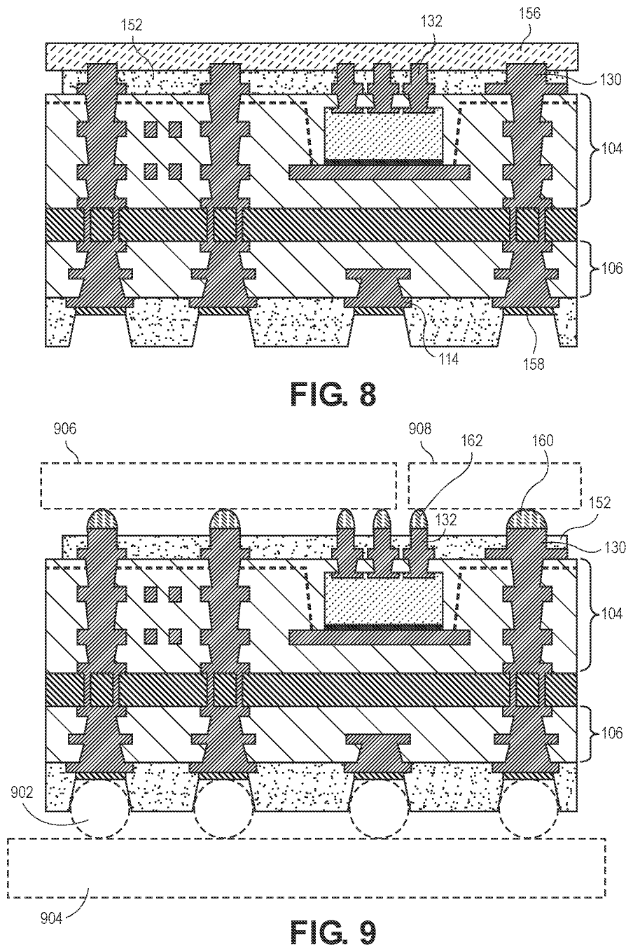

Referring to FIG. 8, a laminate 156, such as a polyethylene terephthalate (PET) laminate, is adhered to the structure of FIG. 7A on the side of the upper package portion 104. In the case that the package substrate includes a lower substrate portion, in one embodiment, a surface finish layer 158 is formed on the conductive bond pads 114. In a particular embodiment, the laminate 156 protects the conductive pillars 130 and 132 during formation of the surface finish layer 158.

Referring to FIG. 9, the laminate 156 is removed. Solder bumps 160 are formed on the conductive pillars 130. Solder bumps 162 are formed on the conductive pillars 132. In one embodiment, the solder bumps 160 and 162 are composed of copper, tin and nickel. As an exemplary embodiment, a first die 906 and a second die 908 are coupled to the solder bumps 160 and 162 of the upper substrate portion 104. In the case that the package substrate includes a lower substrate portion, a board 904, such as a motherboard, is coupled to the lower substrate portion 106 by solder balls 902.

In accordance with an embodiment of the present disclosure, with reference again to FIGS. 1-6, 7A, 7B, 8 and 9, a multi-die interconnect structure includes a package substrate 102/104/106 having a cavity 118. A bridge die 120 is in the cavity 118 of the package substrate 102/104/106, the bridge die 120 including silicon. A dielectric material 128 is over the package substrate 102/104/106, over the bridge die 120, and in the cavity 118. A plurality of conductive bond pads 112/126 is on the dielectric material 128. The multi-die interconnect structure further includes a plurality of conductive pillars 130/132. Individual ones of the plurality of conductive pillars 130/132 are on a corresponding one of the plurality of conductive bond pads 112/126. A solder resist material 152 is on the dielectric material 128, on exposed portions of the plurality of conductive bond pads 112/126, and laterally surrounding the plurality of conductive pillars 130/132. The plurality of conductive pillars 130/132 has a top surface above a top surface of the solder resist material 152.

In one embodiment, the multi-die interconnect structure further includes a plurality of solder bumps 160/162. Individual ones of the plurality of solder bumps 160/162 are on a corresponding one of the plurality of conductive pillars130/132, as is depicted.

In one embodiment, a first portion 112 of the plurality of conductive bond pads is coupled to a first plurality of conductive vias 110. The first plurality of conductive vias 110 is in the package substrate. In one embodiment, a second portion 126 of the plurality of conductive bond pads is coupled to a second plurality of conductive vias 124. The second plurality of conductive vias 124 is in the dielectric material 128. In a particular embodiment, the second plurality of conductive vias 124 is coupled to a plurality of bridge die bond pads 122 of the bridge die 120.

In one embodiment, the bridge die 120 is over a conductive line 109 in the package substrate 102/104/106. In a particular such embodiment, the bridge die 120 is attached to the conductive line 109 by an adhesive layer 121.

In one embodiment, the cavity 118 is in a first side 104 of the package substrate, and the multi-die interconnect structure further includes a second solder resist material 144 on a second side 106 of the package substrate, the second side opposite the first side. In a particular such embodiment, the multi-die interconnect structure further includes a plurality of openings in the second solder resist material 144, the plurality of openings exposing a plurality of backside bond pads 114/158 on the second side 106 of the package substrate.

In an embodiment, a multi-die interconnect structure further includes a plurality of solder balls 902 in the plurality of openings in the second solder resist material 144. Individual ones of the plurality of solder balls 902 are coupled to corresponding ones of the plurality of backside bond pads 114/158. In one embodiment, a board 904 is coupled to the plurality of solder balls 902, as is depicted.

In an embodiment, a first die 906 is electrically coupled to a first portion of the plurality of conductive pillars 130/132. A second die 908 is electrically coupled to a second portion of the plurality of conductive pillars 130/132. In a particular embodiment, the first die 906 is a processor die, and the second die 908 is a memory die. In one embodiment, first die 906 is coupled to the second die 908 by conductive traces of the bridge die 120. Exemplary arrangements for a plurality of dies coupled to a multi-die interconnect structure are described in greater detail below.

In accordance with another embodiment of the present disclosure, with reference again to FIGS. 1-6, 7A, 7B, 8 and 9, a method of fabricating a multi-die interconnect structure includes forming a cavity 118 in a package substrate 104. A bridge die 120 is disposed in the cavity 118 of the package substrate 104, the bridge die 120 including silicon. A dielectric material 128 is formed over the package substrate 104, over the bridge die 120, and in the cavity 118. A plurality of conductive bond pads 112/126 is formed on the dielectric material 128. A plurality of conductive pillars 130/132 is formed, individual ones of the plurality of conductive pillars 130/132 on a corresponding one of the plurality of conductive bond pads 112/126. A solder resist material 134 is formed over the dielectric material 128, over the plurality of conductive bond pads 112/126, and over the plurality of conductive pillars 130/132. The solder resist material 134 is thinned to form a thinned solder resist material 152 on the dielectric material 128, on exposed portions of the plurality of conductive bond pads 112/126, and laterally surrounding the plurality of conductive pillars 130/132. The plurality of conductive pillars 130/132 has a top surface above a top surface of the solder resist material 152.

In another or alternative embodiment, a process flow can include the operations: (1) build up to bridge embedding without seed etch, (2) dry film resist lamination and first level interconnect formation, (3) solder resist lamination on both front and sides, (4) expose backside with mid-level interconnect (MLI) patterning, (5) solder resist thinning on both sides, where front side (via reveal) and backside (solder resist openings are partially thinned an opened), (6) expose front side with epoxy trench patterning while curing the bulk solder resist on the front (no exposure on back), (7) solder resist develop, where the backside forms a metal-defined MLI, (8) PET lamination on front, with backside surface finish plating, and PET removal, (9) further fabrication such as die and board coupling.

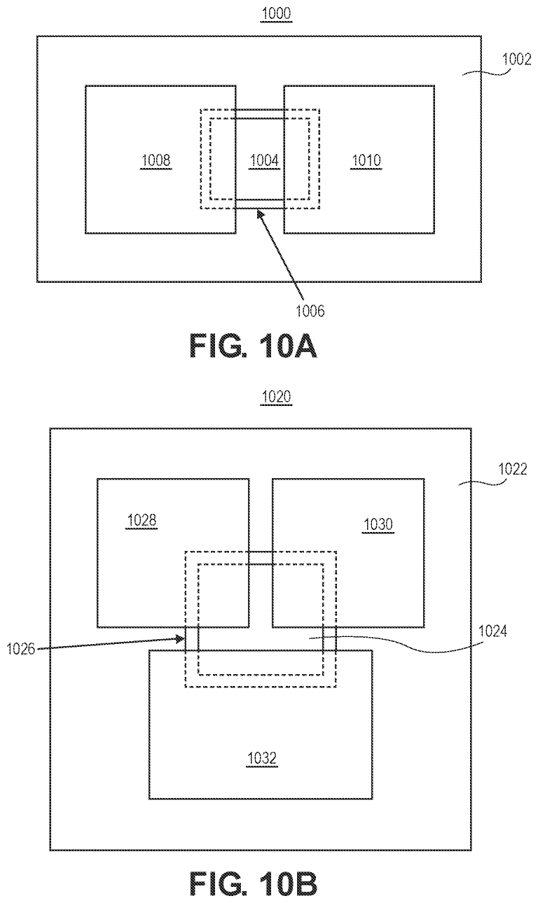

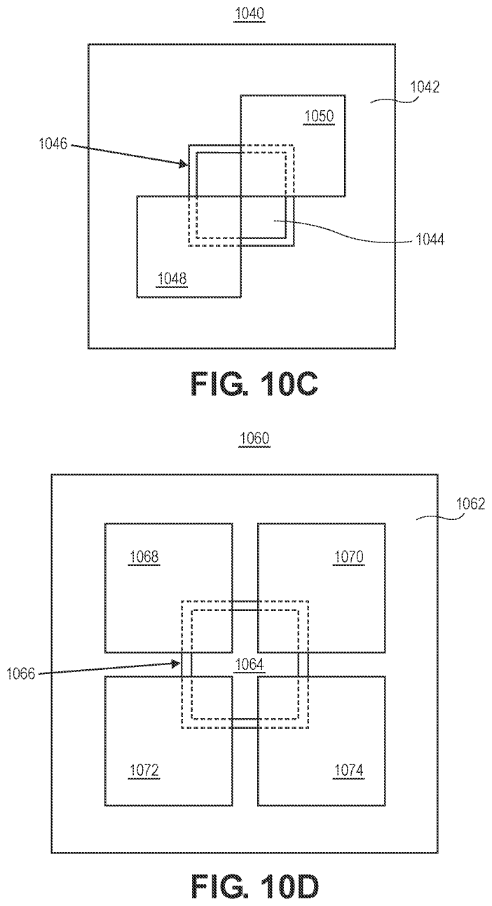

It is to be appreciated that a variety of possibilities exist for bridge die arrangements relative to the interconnected dies. As example, FIGS. 10A-10D are plan view illustrations of various electronic packages with an embedded bridge, in accordance with another embodiment of the present disclosure.

Referring to FIG. 10A, an electronic package 1000 includes a package substrate 1002 having a cavity 1006 therein. A bridge die 1004 is in the cavity 1006. A first die 1008 and a second die 1010 are coupled together by the bridge die 1004. The first die 1008 and the second die 1010 have a linear arrangement with respect to the bridge die 1004.

Referring to FIG. 10B, an electronic package 1020 includes a package substrate 1022 having a cavity 1026 therein. A bridge die 1024 is in the cavity 1026. A first die 1028, a second die 1030, and a third die 1032 are coupled together by the bridge die 1024.

Referring to FIG. 10C, an electronic package 1040 includes a package substrate 1042 having a cavity 1046 therein. A bridge die 1044 is in the cavity 1046. A first die 1048 and a second die 1050 are coupled together by the bridge die 1044. The first die 1048 and the second die 1050 have a diagonal arrangement with respect to the bridge die 1044.

Referring to FIG. 10D, an electronic package 1060 includes a package substrate 1062 having a cavity 1066 therein. A bridge die 1064 is in the cavity 1066. A first die 1068, a second die 1070, a third die 1072, and a fourth die 1074 are coupled together by the bridge die 1064.

In an embodiment, a bridge die as described herein may include any suitable substrate material. In an embodiment, a bridge die as described herein is a silicon (Si) bridge die. In an embodiment, a bridge die as described herein includes glass, ceramic, semiconductor materials (e.g., high or low resistivity silicon, group III-V semiconductors, or the like), or organic substrates (high density interconnect (HDI) substrates, embedded trace substrates (ETS), high density package (HDP) substrates, molded substrates, or the like). In some embodiments, a bridge die is a passive device. That is, the bridge die may include only passive components (e.g., traces, vias, etc.). In other embodiments, the bridge die may be an active interposer. That is, the bridge die may include active devices (e.g., transistors etc.).

In an embodiment, a bridge die has an active surface. While referred to as an “active” surface, it is to be appreciated that the active surface may include entirely passive features. In an embodiment, the bridge die may include through component vias (TCVs). The TCVs may electrically couple the active surface to pads on the backside of the bridge die. In an embodiment, the bridge die has first level interconnects (FLIs) such as a copper bump, a solder, or any other suitable FLI interconnect architecture.

In an embodiment, a plurality of dies coupled by a bridge die may be any type of dies. For example, the dies may be processor dies, memory dies, graphics dies, or the like. In an embodiment, the dies may be embedded in a mold layer. An underfill layer may also partially embed the dies and surround interconnects below the dies, exemplary structures of which are described above.

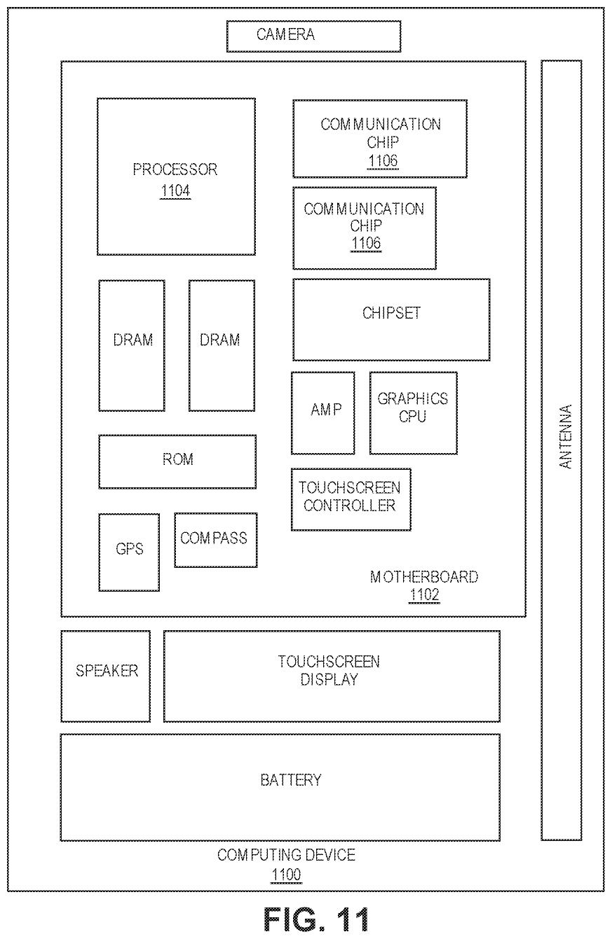

FIG. 11 illustrates a computing device 1100 in accordance with one implementation of the disclosure. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations, the integrated circuit die of the processor 1104 may be part of an electronic package that includes an embedded bridge, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation, the integrated circuit die of the communication chip 1106 may be part of an electronic package that includes an embedded bridge, in accordance with embodiments described herein.

Thus, multi-die package with an embedded bridge and a thinned surface are described herein.

The above description of illustrated implementations, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A multi-die interconnect structure includes a package substrate having a cavity. A bridge die is in the cavity of the package substrate, the bridge die including silicon. A dielectric material is over the package substrate, over the bridge die, and in the cavity. A plurality of conductive bond pads is on the dielectric material. The multi-die interconnect structure further includes a plurality of conductive pillars, individual ones of the plurality of conductive pillars on a corresponding one of the plurality of conductive bond pads. A solder resist material is on the dielectric material, on exposed portions of the plurality of conductive bond pads, and laterally surrounding the plurality of conductive pillars. The plurality of conductive pillars has a top surface above a top surface of the solder resist material.

Example embodiment 2: The multi-die interconnect structure of example embodiment 1, further including a plurality of solder bumps, individual ones of the plurality of solder bumps on a corresponding one of the plurality of conductive pillars.

Example embodiment 3: The multi-die interconnect structure of example embodiment 1 or 2, wherein a first portion of the plurality of conductive bond pads is coupled to a first plurality of conductive vias, the first plurality of conductive vias in the package substrate.

Example embodiment 4: The multi-die interconnect structure of example embodiment 3, wherein a second portion of the plurality of conductive bond pads is coupled to a second plurality of conductive vias, the second plurality of conductive vias in the dielectric material.

Example embodiment 5: The multi-die interconnect structure of example embodiment 4, wherein the second plurality of conductive vias is coupled to a plurality of bridge die bond pads of the bridge die.

Example embodiment 6: The multi-die interconnect structure of example embodiment 1, 2, 3, 4 or 5, wherein the bridge die is over a conductive line in the package substrate.

Example embodiment 7: The multi-die interconnect structure of example embodiment 6, wherein the bridge die is attached to the conductive line by an adhesive layer.

Example embodiment 8: The multi-die interconnect structure of example embodiment 1, 2, 3, 4, 5, 6 or 7, wherein the cavity is in a first side of the package substrate, the multi-die interconnect structure further including a second solder resist material on a second side of the package substrate, the second side opposite the first side.

Example embodiment 9: The multi-die interconnect structure of example embodiment 8, further including a plurality of openings in the second solder resist material, the plurality of openings exposing a plurality of backside bond pads on the second side of the package substrate.

Example embodiment 10: The multi-die interconnect structure of example embodiment 9, further including a plurality of solder balls in the plurality of openings in the second solder resist material, individual ones of the plurality of solder balls coupled to corresponding ones of the plurality of backside bond pads.

Example embodiment 11: An IC assembly includes a package substrate having a cavity. A bridge die is in the cavity of the package substrate, the bridge die including silicon. A dielectric material is over the package substrate, over the bridge die, and in the cavity. A plurality of conductive bond pads is on the dielectric material. The multi-die interconnect structure further includes a plurality of conductive pillars, individual ones of the plurality of conductive pillars on a corresponding one of the plurality of conductive bond pads. A solder resist material is on the dielectric material, on exposed portions of the plurality of conductive bond pads, and laterally surrounding the plurality of conductive pillars. The plurality of conductive pillars has a top surface above a top surface of the solder resist material. A first die is electrically coupled to a first portion of the plurality of conductive pillars. A second die is electrically coupled to a second portion of the plurality of conductive pillars.

Example embodiment 12: The integrated circuit (IC) assembly of example embodiment 11, wherein the first die is a processor die, and the second die is a memory die.

Example embodiment 13: The IC assembly of example embodiment 11 or 12, wherein the cavity is in a first side of the package substrate, the IC assembly further including a second solder resist material on a second side of the package substrate, the second side opposite the first side.

Example embodiment 14: The IC assembly of example embodiment 13, further including a plurality of openings in the second solder resist material, the plurality of openings exposing a plurality of backside bond pads on the second side of the package substrate.

Example embodiment 15: The IC assembly of example embodiment 14, further including a plurality of solder balls in the plurality of openings in the second solder resist material, individual ones of the plurality of solder balls coupled to corresponding ones of the plurality of backside bond pads.

Example embodiment 16: The IC assembly of example embodiment 14, further including a board coupled to the plurality of solder balls.

Example embodiment 17: The IC assembly of example embodiment 11, 12, 13, 14, 15 or 16, further including a plurality of solder bumps, individual ones of the plurality of solder bumps on a corresponding one of the plurality of conductive pillars.

Example embodiment 18: The IC assembly of example embodiment 11, 12, 13, 14, 15, 16 or 17, wherein a first portion of the plurality of conductive bond pads is coupled to a first plurality of conductive vias, the first plurality of conductive vias in the package substrate.

Example embodiment 19: The IC assembly of example embodiment 18, wherein a second portion of the plurality of conductive bond pads is coupled to a second plurality of conductive vias, the second plurality of conductive vias in the dielectric material.

Example embodiment 20: The IC assembly of example embodiment 19, wherein the second plurality of conductive vias is coupled to a plurality of bridge die bond pads of the bridge die.

Example embodiment 21: The IC assembly of example embodiment 11, 12, 13, 14, 15, 16, 17, 18, 19 or 20, wherein the bridge die is over a conductive line in the package substrate.

Example embodiment 22: The IC assembly of example embodiment 21, wherein the bridge die is attached to the conductive line by an adhesive layer.

Example embodiment 23: A method of fabricating a multi-die interconnect structure includes forming a cavity in a package substrate. A bridge die is disposed in the cavity of the package substrate, the bridge die including silicon. A dielectric material is formed over the package substrate, over the bridge die, and in the cavity. A plurality of conductive bond pads is formed on the dielectric material. A plurality of conductive pillars is formed, individual ones of the plurality of conductive pillars on a corresponding one of the plurality of conductive bond pads. A solder resist material is formed over the dielectric material, over the plurality of conductive bond pads, and over the plurality of conductive pillars. The solder resist material is thinned to form a thinned solder resist material on the dielectric material, on exposed portions of the plurality of conductive bond pads, and laterally surrounding the plurality of conductive pillars. The plurality of conductive pillars has a top surface above a top surface of the solder resist material.

Example embodiment 24: The method of example embodiment 23, further including forming a plurality of solder bumps, individual ones of the plurality of solder bumps on a corresponding one of the plurality of conductive pillars.

Example embodiment 25: The method of example embodiment 23 or 24, wherein a first portion of the plurality of conductive bond pads is coupled to a first plurality of conductive vias, the first plurality of conductive vias in the package substrate.

What is claimed is:

1. A multi-die interconnect structure, comprising:
a package substrate having a cavity;
a bridge die in the cavity of the package substrate, the bridge die comprising silicon;
a dielectric material over the package substrate, over the bridge die, and in the cavity;
a plurality of conductive bond pads on the dielectric material;
a plurality of conductive pillars, individual ones of the plurality of conductive pillars on a corresponding one of the plurality of conductive bond pads; and
a solder resist material on the dielectric material, on exposed portions of the plurality of conductive bond pads, and laterally surrounding the plurality of conductive pillars, wherein the plurality of conductive pillars has a top surface above a top surface of the solder resist material.

2. The multi-die interconnect structure of claim 1, further comprising:
a plurality of solder bumps, individual ones of the plurality of solder bumps on a corresponding one of the plurality of conductive pillars.

3. The multi-die interconnect structure of claim 1, wherein a first portion of the plurality of conductive bond pads is coupled to a first plurality of conductive vias, the first plurality of conductive vias in the package substrate.

4. The multi-die interconnect structure of claim 3, wherein a second portion of the plurality of conductive bond pads is coupled to a second plurality of conductive vias, the second plurality of conductive vias in the dielectric material.

5. The multi-die interconnect structure of claim 4, wherein the second plurality of conductive vias is coupled to a plurality of bridge die bond pads of the bridge die.

6. The multi-die interconnect structure of claim 1, wherein the bridge die is over a conductive line in the package substrate.

7. The multi-die interconnect structure of claim 6, wherein the bridge die is attached to the conductive line by an adhesive layer.

8. The multi-die interconnect structure of claim 1, wherein the cavity is in a first side of the package substrate, the multi-die interconnect structure further comprising:
a second solder resist material on a second side of the package substrate, the second side opposite the first side.

9. The multi-die interconnect structure of claim 8, further comprising:
a plurality of openings in the second solder resist material, the plurality of openings exposing a plurality of backside bond pads on the second side of the package substrate.

10. The multi-die interconnect structure of claim 9, further comprising:
a plurality of solder balls in the plurality of openings in the second solder resist material, individual ones of the plurality of solder balls coupled to corresponding ones of the plurality of backside bond pads.

11. An integrated circuit (IC) assembly, comprising:
a package substrate having a cavity;
a bridge die in the cavity of the package substrate, the bridge die comprising silicon;
a dielectric material over the package substrate, over the bridge die, and in the cavity;
a plurality of conductive bond pads on the dielectric material;
a plurality of conductive pillars, individual ones of the plurality of conductive pillars on a corresponding one of the plurality of conductive bond pads;
a solder resist material on the dielectric material, on exposed portions of the plurality of conductive bond pads, and laterally surrounding the plurality of conductive pillars, wherein the plurality of conductive pillars has a top surface above a top surface of the solder resist material;
a first die electrically coupled to a first portion of the plurality of conductive pillars; and
a second die electrically coupled to a second portion of the plurality of conductive pillars.

12. The IC assembly of claim 11, wherein the first die is a processor die, and the second die is a memory die.

13. The IC assembly of claim 11, wherein the cavity is in a first side of the package substrate, the IC assembly further comprising:
a second solder resist material on a second side of the package substrate, the second side opposite the first side.

14. The IC assembly of claim 13, further comprising:
a plurality of openings in the second solder resist material, the plurality of openings exposing a plurality of backside bond pads on the second side of the package substrate.

15. The IC assembly of claim 14, further comprising:
a plurality of solder balls in the plurality of openings in the second solder resist material, individual ones of the plurality of solder balls coupled to corresponding ones of the plurality of backside bond pads.

16. The IC assembly of claim 15, further comprising:
a board coupled to the plurality of solder balls.

17. The IC assembly of claim 11, further comprising:
a plurality of solder bumps, individual ones of the plurality of solder bumps on a corresponding one of the plurality of conductive pillars.

18. The IC assembly of claim 11, wherein a first portion of the plurality of conductive bond pads is coupled to a first plurality of conductive vias, the first plurality of conductive vias in the package substrate.

19. The IC assembly of claim 18, wherein a second portion of the plurality of conductive bond pads is coupled to a second plurality of conductive vias, the second plurality of conductive vias in the dielectric material.

20. The IC assembly of claim 19, wherein the second plurality of conductive vias is coupled to a plurality of bridge die bond pads of the bridge die.

21. The IC assembly of claim 11, wherein the bridge die is over a conductive line in the package substrate.

22. The IC assembly of claim 21, wherein the bridge die is attached to the conductive line by an adhesive layer.

23. A method of fabricating a multi-die interconnect structure, the method comprising:
forming a cavity in a package substrate;
disposing a bridge die in the cavity of the package substrate, the bridge die comprising silicon;
forming a dielectric material over the package substrate, over the bridge die, and in the cavity;
forming a plurality of conductive bond pads on the dielectric material;
forming a plurality of conductive pillars, individual ones of the plurality of conductive pillars on a corresponding one of the plurality of conductive bond pads;
forming a solder resist material over the dielectric material, over the plurality of conductive bond pads, and over the plurality of conductive pillars; and
thinning the solder resist material to form a thinned solder resist material on the dielectric material, on exposed portions of the plurality of conductive bond pads, and laterally surrounding the plurality of conductive pillars, wherein the plurality of conductive pillars has a top surface above a top surface of the solder resist material.

24. The method of claim 23, further comprising:
forming a plurality of solder bumps, individual ones of the plurality of solder bumps on a corresponding one of the plurality of conductive pillars.

25. The method of claim 23, wherein a first portion of the plurality of conductive bond pads is coupled to a first plurality of conductive vias, the first plurality of conductive vias in the package substrate.
